(19) United States
(12) Patent Application Publication
(10) Pub. No.: US 2016/0192522 A1
(43) Pub. Date: Jun. 30, 2016

(54) ELECTRONIC DEVICE ENCLOSURE

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: YU-MING XIAO, Wuhan (CN); LIANG-CHIN WANG, New Taipei (TW); ZAN LI, Wuhan (CN); WEI GUO, Wuhan (CN)

(21) Appl. No.: 14/594,612

(22) Filed: Jan. 12, 2015

(30) Foreign Application Priority Data
Dec. 25, 2014 (CN) 201410819137.X

(51) Int. Cl. H05K 5/02; H05K 5/06; H05K 5/03

(52) U.S. Cl. CPC H05K 5/0239; H05K 5/03; H05K 5/0226; H05K 5/06

(57) ABSTRACT

Electronic device enclosure includes a main body and a cover. The main body includes a first sidewall and a second sidewall opposite to the first sidewall. The cover is rotatably coupled to the first sidewall and includes a cover main body. The cover is foldable relative to the first sidewall to secure to the second sidewall. The cover main body is made of non-metallic material, and a top moisture proof member is attached to a top surface of the cover main body to protect the cover main body from moisture.

### FIELD

The subject matter herein generally relates to an electronic device enclosure.

### BACKGROUND

An electronic device enclosure such as a personal computer chassis often includes a main body and a cover attached to the main body. The main body generally includes a bottom plate, two side plates, and a top plate cooperatively defining a receiving area for receiving electronic components. The electronic components can include a motherboard, hard disks, a plurality of expansion cards, and a power supply.

### BRIEF DESCRIPTION OF THE DRAWINGS

Implementations of the present technology will now be described, by way of example only, with reference to the attached figures.

FIG. 1 is an isometric view of an embodiment of an electronic device enclosure, and a cover is opened relative to a main body of the electronic device enclosure.

FIG. 2 is similar to FIG. 1, and the cover is closed relative to the main body of the electronic device enclosure.

FIG. 3 is a cross-section view of FIG. 2, taken along a line III-III.

FIG. 4 is an enlarged view of a circle portion IV of FIG. 3.

FIG. 5 is an enlarged view of a circle portion V of FIG. 3.

FIG. 6 is an enlarged view of a circle portion VI of FIG. 3.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to an electronic device enclosure including a main body and a cover. The main body includes a first sidewall and a second sidewall opposite to the first sidewall. The cover is rotatably coupled to the first sidewall and includes a cover main body. The cover is foldable relative to the first sidewall to secure to the second sidewall. The cover main body is made of non-metallic material, and a top moisture proof member is attached to a top surface of the cover main body to protect the cover main body from moisture.

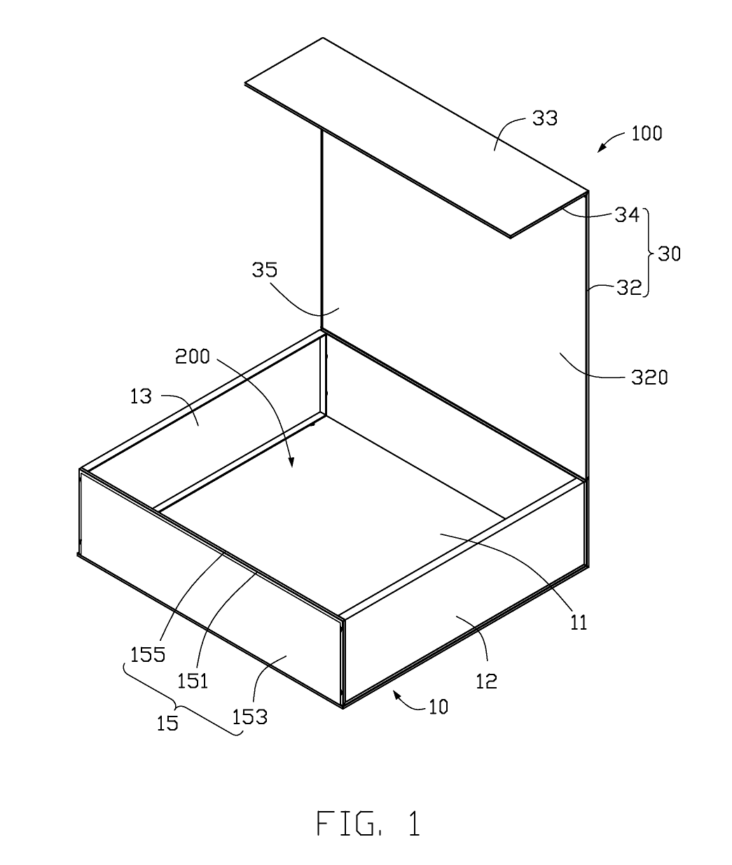

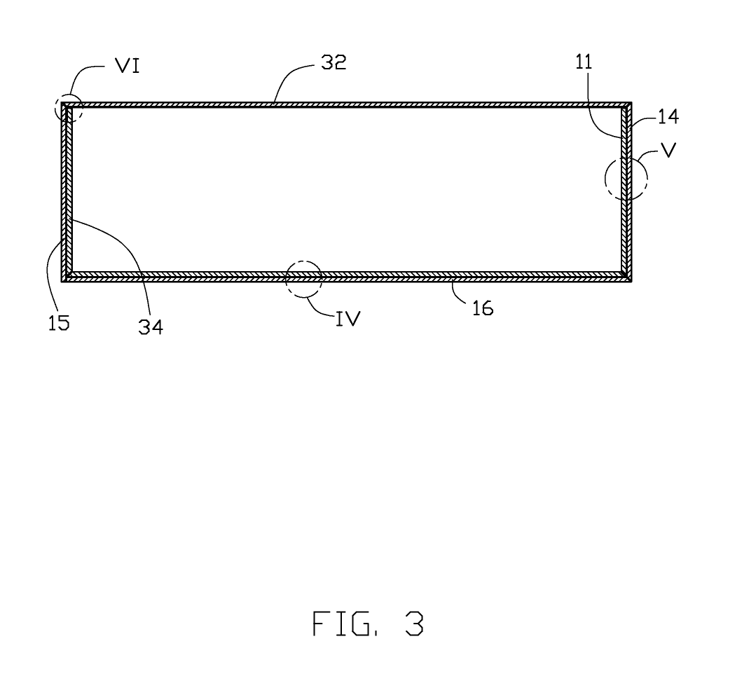

FIGS. 1-3 illustrate an embodiment of an electronic device enclosure 100.

The electronic device enclosure 100 can include a main body 10 and a cover 30 configured to be attached to the main body 10. In at least one embodiment, the electronic device enclosure 100 can be a computer chassis.

The main body 10 can include a base 11, a front wall 12 connected to a first edge of the base 11, a rear wall 13 connected to a second edge of the base 11, a first sidewall 14, and a second sidewall 15.

The base 11 is substantially U-shaped, the first sidewall 14 is attached to a first side portion of the base 11, and the second sidewall 15 is attached to a second side portion of the base 11. In at least one embodiment, the front panel 12 is substantially parallel to the rear panel 13 and perpendicular to a bottom portion of the base 11, the first sidewall 14 is substantially parallel to the second sidewall 15 and perpendicular to the bottom portion of the base 11. The base 11, the front panel 12, the rear panel 13, the first sidewall 14, and the second sidewall 15 cooperatively define a receiving space 200 which is configured to receive a plurality of electronic components. The plurality of electronic components can include a motherboard, hard disks, a plurality of expansion cards, a power supply, and so on.

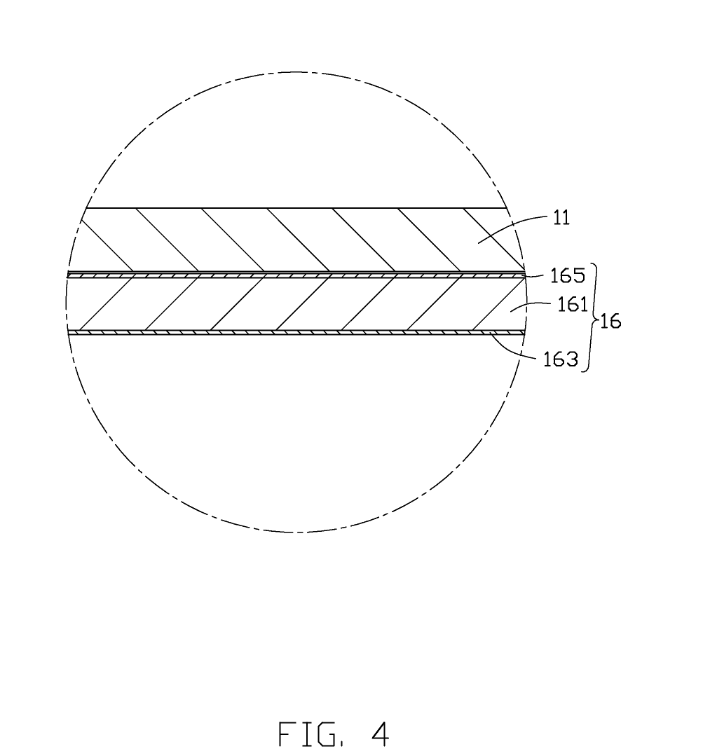

FIGS. 1 and 4 illustrate a strengthening plate 16 being attached to a bottom surface of the base 11. The strengthening plate 16 is coupled to the first sidewall 14 and the second sidewall 15. The strengthening plate 16 can include a plate main body 161, a top moisture proof member 163, and a bottom moisture proof member 165. The top moisture proof member 163 is attached to a top surface of the plate main body 161, and the bottom moisture proof member 165 is attached to a bottom surface of the plate main body 161. In at least one embodiment, the top moisture proof member 163 is an epidermal paper, such as a laminating paper, and the bottom moisture proof member 165 is an aluminized paper. The top moisture proof member 163 and the bottom moisture proof member 165 can together protect the plate main body 161 from moisture. In at least one embodiment, the plate main body 161 is made of non-metallic material, such as paper, wood, bamboo, plastic, etc. The non-metallic material can be lighter than metal.

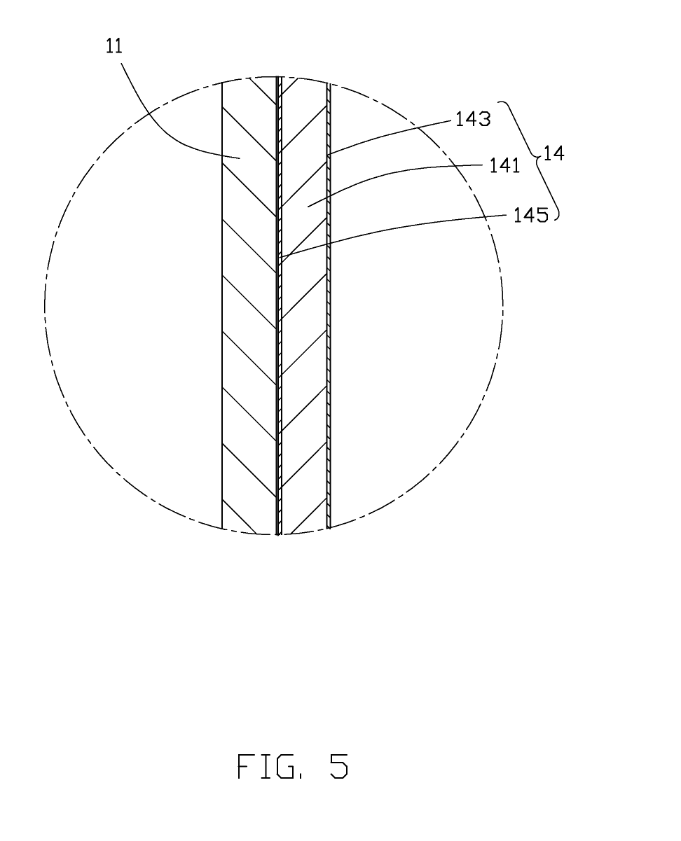

FIGS. 1 and 5 illustrate the first sidewall 14 which is coupled to a first edge of the strengthening plate 16. The first sidewall 14 can include a first sidewall main body 141, a top moisture proof member 143, and a bottom moisture proof member 145. The top moisture proof member 143 is attached to a top surface of first sidewall main body 141 and the bottom moisture proof member 165 is attached to a bottom surface of the first sidewall main body 141. In at least one embodiment, the top moisture proof member 143 is an epidermal paper, such as a laminating paper, and the bottom moisture proof member 145 is an aluminized paper. The top moisture proof member 143 and the bottom moisture proof member 145 can together protect the first sidewall main body 141 from moisture. In at least one embodiment, the first sidewall main body 141 is made of non-metallic material, such as paper, wood, bamboo, plastic, etc. The non-metallic material can be lighter than metal.

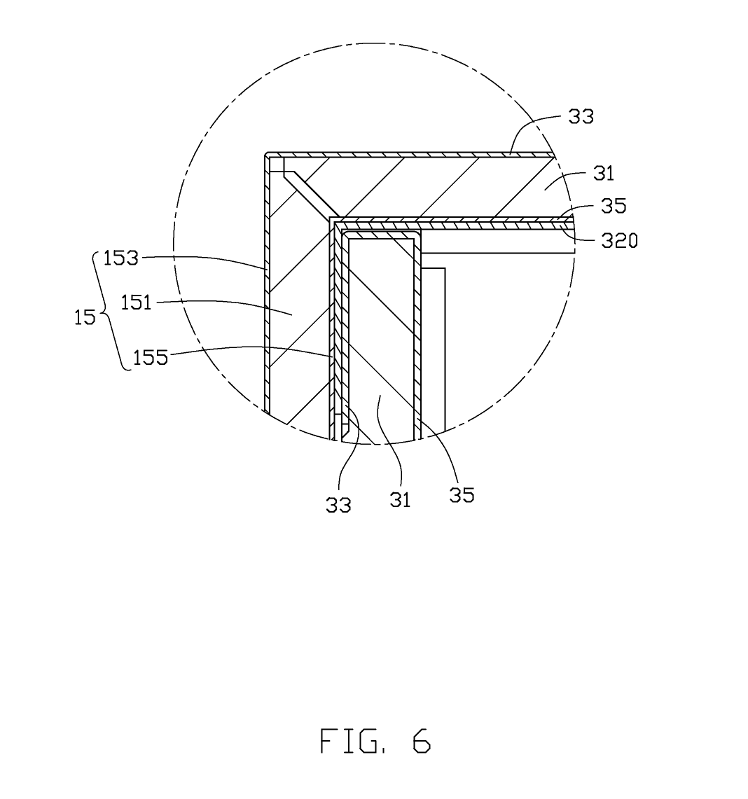

FIGS. 1 and 6 illustrate the second sidewall 15 which is coupled to a second edge of the strengthening plate 16. The second sidewall 15 can include a second sidewall main body 151, a top moisture proof member 153, and a bottom moisture proof member 155. The top moisture proof member 153 is attached to a top surface of the second sidewall main body 151 and the bottom moisture proof member 155 is attached to a bottom surface of the second sidewall main body 151. In at least one embodiment, the top moisture proof member 153 is an epidermal paper, such as a laminating paper, and the bottom moisture proof member 155 is an aluminized paper. The top moisture proof member 153 and the bottom moisture proof member 155 can together protect the second sidewall main body 151 from moisture. In at least one embodiment, the second sidewall main body 151 is made of non-metallic material, such as paper, wood, bamboo, plastic, etc. The non-metallic material can be lighter than metal.

FIGS. 1 and 6 illustrate the cover 30 which is coupled to a top edge of the first sidewall 14. The cover 30 can include a cover main body 31, a top moisture proof member 33, and a bottom moisture proof member 35. The top moisture proof member 33 is attached to a top surface of the cover main body 31 and the bottom moisture proof member 35 is attached to a bottom surface of the cover main body 31. In at least one embodiment, the top moisture proof member 33 is an epidermal paper, such as a laminating paper, and the bottom moisture proof member 35 is an aluminized paper. The top moisture proof member 33 and the bottom moisture proof member 35 can together protect the cover main body 31 from moisture. In at least one embodiment, the cover main body 31 is made of non-metallic material, such as paper, wood, bamboo, plastic, etc. The non-metallic material can be lighter than metal.

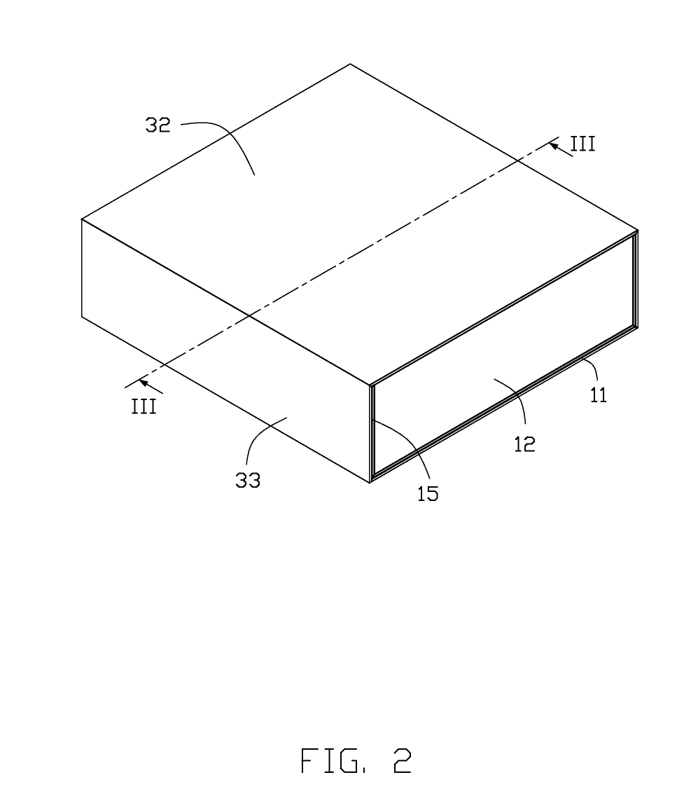

FIGS. 1 and 2 illustrate the cover 30 including a shielding portion 32 rotatably coupled to the first sidewall 14 and a securing portion 34 coupled to the shielding portion 32. The shielding portion 32 can be folded relative to the first sidewall 14 for allowing the securing portion 34 to be secured to the second sidewall 15. In at least one embodiment, an attaching plate 320 is secured to the shielding portion 32 for strengthening the configuration of the shielding portion 32. When the securing portion 34 is secured to the second sidewall 15, the securing portion 34 is adhered to the inner surface of the second sidewall 15, and the shielding portion 32 can cover the plurality of electronic components into the receiving space 200. That is, the securing portion 34 is adhered to the bottom moisture proof member 155. In at least one embodiment, the securing portion 34 is secured to the bottom moisture proof member 155 by means, such as clipping, pasting.

The top moisture proof member 163 is attached to a top surface of the plate main body 161, and the bottom moisture proof member 165 is attached to a bottom surface of the plate main body 161. The top moisture proof member 143 is attached to a top surface of first sidewall main body 141 and the bottom moisture proof member 165 is attached to a bottom surface of the first sidewall main body 141. The top moisture proof member 153 is attached to a top surface of the second sidewall main body 151 and the bottom moisture proof member 155 is attached to a bottom surface of the second sidewall main body 151. The top moisture proof member 33 is attached to a top surface of the cover main body 31 and the bottom moisture proof member 35 is attached to a bottom surface of the cover main body 31. Therefore, the top moisture proof member 163, 143, 153, 33 and the bottom moisture proof member 165, 145, 155, 35 together protect the plate main body 161, the first sidewall main body 141, the second sidewall main body 151, and the cover main body 31 from moisture.

In at least one embodiment, the cover 30, the strengthening plate 16, the first sidewall 14, and the second sidewall 15 are integrated to form an integrated member which a top moisture proof member is attached on a top surface and the bottom moisture proof member attached on a bottom surface.

The embodiments shown and described above are only examples. Many details are often found in the art such as the other features of an electronic device enclosure. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. An electronic device enclosure comprising:
a main body comprising a first sidewall and a second sidewall opposite to the first sidewall; and
a cover rotatably coupled to the first sidewall and comprising a cover main body;
wherein the cover is foldable relative to the first sidewall to secure to the second sidewall, the cover main body is made of non-metallic material, and a top moisture proof member is attached to a top surface of the cover main body to protect the cover main body from moisture.

2. The electronic device enclosure of claim 1, wherein the cover comprises a shielding portion rotatably coupled to the first sidewall and a securing portion coupled to the shielding portion, and the shielding portion is rotatable relative to the first sidewall for allowing the securing portion to secure to the second sidewall.

3. The electronic device enclosure of claim 2, wherein the securing portion is rotatably coupled to the shielding portion, and the securing portion is attached to an inner surface of the second sidewall when the securing portion is secured to the second sidewall.

4. The electronic device enclosure of claim 1, wherein the top moisture proof member is an epidermal paper.

5. The electronic device enclosure of claim 4, wherein the epidermal paper is a laminating paper.

6. The electronic device enclosure of claim 1, wherein a bottom moisture proof member is attached to a bottom surface of the cover main body to protect the cover main body from moisture.

7. The electronic device enclosure of claim 1, wherein the first sidewall comprises a first sidewall main body, an epidermal paper is attached to a top surface of the first sidewall main body, and an aluminized paper is attached to a bottom surface of the first sidewall.

8. The electronic device enclosure of claim 1, further comprising a strengthening plate, wherein the strengthening plate, the cover, the first sidewall and the second sidewall are integrated.

9. The electronic device enclosure of claim 1, wherein the main body further comprises a base, the strengthening plate is below the base, the first sidewall extends from a first edge of the strengthening plate, the second sidewall extends from a second edge of the strengthening plate, and the cover extends from a top edge of the first sidewall.

10. An electronic device enclosure comprising:
a main body comprising a base, a strengthening plate located below the base, a first sidewall attached to a first side of the base and a second sidewall opposite to the first sidewall and attached to a second opposite side of the base; and
a cover rotatably coupled to the first sidewall, and the strengthening plate, the cover, the first sidewall and the second sidewall are integrated;
wherein a top moisture proof member is attached to a top surface of the strengthening plate, the cover, the first sidewall and the second sidewall, and a bottom moisture proof member is attached to a bottom surface of the strengthening plate, the cover, the first sidewall and the second sidewall to protect the strengthening plate, the cover, the first sidewall and the second sidewall from moisture.

11. The electronic device enclosure of claim 10, wherein the cover is foldable relative to the first sidewall to secure to the second sidewall, the cover comprises a cover main body made of non-metallic material, and the top moisture proof member is attached to a top surface of the cover main body.

12. The electronic device enclosure of claim 11, wherein the cover comprises a shielding portion rotatably coupled to the first sidewall and a securing portion coupled to the shielding portion, and the shielding portion is rotatable relative to the first sidewall for allowing the securing portion to secure to the second sidewall.

13. The electronic device enclosure of claim 12, wherein the securing portion is rotatably coupled to the shielding portion, and the securing portion is attached to an inner surface of the second sidewall when the securing portion is secured to the second sidewall.

14. The electronic device enclosure of claim 11, wherein the top moisture proof member is an epidermal paper.

15. The electronic device enclosure of claim 14, wherein the epidermal paper is a laminating paper.

16. The electronic device enclosure of claim 11, wherein the bottom moisture proof member is an aluminized paper.

17. The electronic device enclosure of claim 11, wherein the first sidewall extends from a first edge of the strengthening plate, the second sidewall extends from a second edge of the strengthening plate, and the cover extends from a top edge of the first sidewall.
